(19) United States
(12) Patent Application Publication
(10) Pub. No.: US 2026/0262419 A1
(43) Pub. Date: Sep. 3, 2026

(54) ELECTRONIC DEVICE AND METHOD OF PROVIDING THE SAME

(71) Applicant: Samsung Display Co., Ltd., Yongin-si (KR)

(72) Inventors: WONBEOM LEE, Yongin-si (KR); YONG-HOON KWON, Yongin-si (KR); TAEOH KIM, Yongin-si (KR)

(21) Appl. No.: 19/377,438

(22) Filed: Nov. 3, 2025

(30) Foreign Application Priority Data
Feb. 28, 2025 (KR) 10-2025-0026819

(51) Int. Cl. H10K 59/80; H10K 59/12

(52) U.S. Cl. CPC H10K 59/873; H10K 59/1201

(57) ABSTRACT

An electronic device includes a window module, a display panel facing the window module, and a lower member facing the window module with the display panel therebetween. The display panel includes a substrate including a polymer area providing a front surface facing the window module, and a graphene area which is on the polymer area and provides a rear surface opposite to the front surface, a pixel on the substrate, and a metal layer on the rear surface of the substrate.

### CROSS REFERENCE TO RELATED APPLICATION

This application claims priority to Korean Patent Application No. 10-2025-0026819 filed on Feb. 28, 2025, and all the benefits accruing therefrom under 35 U.S.C. §119, the disclosures of which are incorporated by reference herein in their entireties.

### BACKGROUND

### 1. Field

Embodiments of the present disclosure described herein relate to an electronic device and a method of manufacturing (or providing) the same. More particularly, embodiments relate to an electronic device having improved reliability.

### 2. Description of the Related Art

Various display devices used in electronic devices such as televisions, mobile phones, tablet computers, and game consoles have been developed. A display device may include various functional layers to provide a color image having excellent quality to a user.

Research on thin display devices is being conducted in order to implement various types of display devices such as display devices including curved surfaces, rollable display devices, or foldable display devices.

### SUMMARY

A thin display device may be implemented by reducing the number of functional layers and including a single functional layer including various functions. In implementing the thin display device, impact resistance of the display device should be secured simultaneously. Accordingly, research on a structure of the display device having a small thickness and excellent impact resistance at the same time is being conducted.

Embodiments of the present disclosure provide an electronic device including a cover panel having a reduced thickness.

According to an embodiment, an electronic device includes a display panel including a substrate including a front surface and a rear surface, a pixel disposed on the substrate, and a metal layer disposed on the rear surface of the substrate, a lower member disposed below the metal layer, and a window module disposed on the display panel, where the substrate includes a graphene area which provides the rear surface and a polymer area which provides the front surface.

The polymer area may include at least one of polyimide, polyarylene ether, polyurethane, and polyacetylene.

The lower member may include a cushion layer, a support layer disposed below the cushion layer, and an adhesive layer disposed between the cushion layer and the support layer.

The electronic device may further include a circuit board disposed on a rear surface of the display panel and connected to the display panel, where the circuit board may be in contact with the support layer.

The metal layer may be in contact with the rear surface of the substrate and the adhesive layer.

A boundary surface between the graphene area and the polymer area may not be flatter than the front surface of the substrate.

The metal layer may be in contact with the graphene area.

The metal layer may include any one of copper (Cu), gold (Au), silver (Ag), and platinum (Pt).

The pixel may include a circuit element layer and a display element layer disposed on the circuit element layer, and the front surface of the substrate may be in contact with a rear surface of the circuit element layer.

A thickness of the graphene area may be in a range of 1μm to 20μm.

An area of the graphene area may be smaller than an area of the polymer area on a plane.

According to an embodiment, a method of manufacturing an electronic device includes providing an initial substrate including a normal area, radiating a laser beam to one surface of the initial substrate so that a portion of the normal area is formed as a graphene area, forming a pixel on the normal area, forming a metal layer on the graphene area, and attaching a lower member to the metal layer.

In the radiating of the laser beam, the laser beam may be any one of an ultraviolet laser (UV laser), a green laser, an infrared laser (IR laser), and a carbon dioxide laser (CO₂ laser).

In the radiating of the laser beam, a radiation depth of the laser beam may be in a range of about 1 micrometer (μm) to about 20 micrometers (μm).

The graphene area may be formed to a central point spaced apart from the one surface of the initial substrate by a certain depth on a cross section, and the certain depth may correspond to the radiation depth of the laser beam from the one surface.

The forming of the metal layer may include providing a substrate including the graphene area and the normal area to an electrolytic solution, providing a metal plate to the electrolytic solution so that the metal plate is spaced apart from the substrate, and applying a voltage to the graphene area and the metal plate, and the metal plate and the electrolytic solution may include the same metal.

The electrolytic solution may include ions of any one of copper (Cu), gold (Au), silver (Ag), and platinum (Pt).

The metal layer may be formed by coating the graphene area with the metal.

The forming of the pixel may be performed after the forming of the metal layer.

The forming of the pixel may be performed before the forming of the metal layer.

### BRIEF DESCRIPTION OF THE FIGURES

The above and other objects and features of the present disclosure will become apparent by describing in detail embodiments thereof with reference to the accompanying drawings.

FIG. 1 is a block diagram of an electronic device according to an embodiment of the present disclosure.

FIG. 2 is schematic views illustrating various electronic devices according to an embodiment.

FIG. 3 is a perspective view of the electronic device according to an embodiment of the present disclosure.

FIG. 4 is an exploded perspective view of the electronic device according to an embodiment of the present disclosure.

FIG. 5 is a cross-sectional view of an electronic device according to an embodiment of the present disclosure.

FIG. 6A is a cross-sectional view of the display panel according to an embodiment of the present disclosure.

FIG. 6B is a rear view of the display panel according to an embodiment of the present disclosure.

FIG. 7A is a cross-sectional view of the display panel according to an embodiment of the present disclosure.

FIG. 7B is a rear view of the display panel according to an embodiment of the present disclosure.

FIG. 8 is a cross-sectional view of the display panel according to an embodiment of the present disclosure.

FIG. 9 is an enlarged cross-sectional view of one area of a substrate according to an embodiment of the present disclosure.

FIG. 10 is a cross-sectional view of the electronic device according to an embodiment of the present disclosure.

FIG. 11 is a cross-sectional view of the electronic device according to an embodiment of the present disclosure.

FIGS. 12A to 12G are cross-sectional views illustrating some of operations of a method for manufacturing an electronic device according to an embodiment of the present disclosure.

### DETAILED DESCRIPTION

Since the present disclosure is variously modified and has various forms, an embodiment thereof will be illustrated in the drawings and will be described herein in detail. However, it should be understood that the present disclosure is not limited to a specific disclosure and includes all changes, equivalents, and substitutes included in the spirit and scope of the present disclosure.

In the specification, the expression that a first component (or an area, a layer, a part, a portion, etc.) is “disposed on”, “connected with” or “coupled to” a second component means that the first component is directly disposed on/connected with/coupled to the second component or means that a third component is interposed therebetween.

The same reference numerals refer to the same components. Within the Figures and the text of the disclosure, a reference number indicating a singular form of an element may also be used to reference a plurality of the element . Further, in the drawings, the thickness, the ratio, and the dimension of components are exaggerated for effective description of technical contents.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” The term “and/or” includes all combinations of one or more components that may be defined by associated components.

Although the terms “first”, “second”, etc. may be used to describe various components, the components should not be limited by the terms. The terms are only used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

In the specification, the wording “directly disposed,” etc. may mean that there is no layer, no film, no area, no plate, and the like added between a part such as a layer, a film, an area, and a plate, and other parts. For example, the wording “directly disposed” may mean that an additional member such as an adhesive member is not disposed between two layers or two members.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value.

Unless otherwise defined, all terms (including technical terms and scientific terms) used in the specification have the same meaning as commonly understood by those skilled in the art to which the present disclosure belongs. Further, terms such as terms defined in the dictionaries commonly used should be interpreted as having a meaning consistent with the meaning in the context of the related technology and should not be interpreted in overly ideal or overly formal meanings unless explicitly defined herein.

Hereinafter, a display device according to an embodiment will be described with reference to the accompanying drawings.

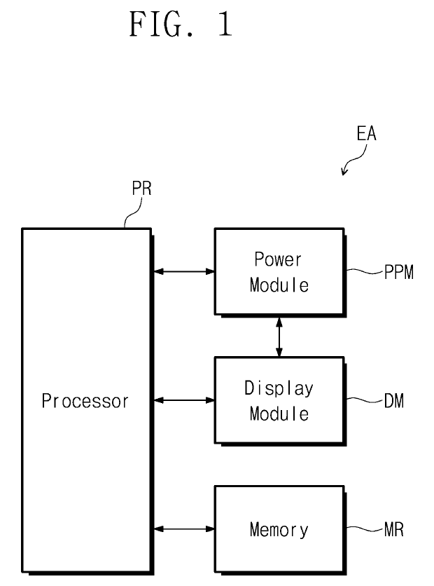

FIG. 1 is a block diagram of an electronic device according to an embodiment of the present disclosure.

Referring to FIG. 1, an electronic device EA according to an embodiment may include a display module DM, a processor PR, a memory MR, and a power module PPM.

The processor PR may include at least one of a central processing unit (CPU), an application processor (AP), a graphic processing unit (GPU), a communication processor (CP), an image signal processor (ISP), and a controller.

Data information required for operating the processor PR or the display module DM may be stored in the memory MR. When the processor PR executes an application stored in the memory MR, an image data signal and/or an input control signal may be transmitted to the display module DM, and the display module DM may process the received signal and output image information through a display screen. The display module DM may include a display panel which displays an image.

The power module PPM may include a power conversion module. The power conversion module may convert power supplied by a power supply module such as a power adapter or a battery device to generate power required for operating the electronic device EA.

At least one of components of the electronic device EA may be included in a display module according to an embodiment, which will be described below, and a display device according to an embodiment including the same. Further, some of individual modules functionally included inside one module may be included inside the display device, and the others thereof may be provided separately from the display device. For example, the display device may include the display module DM, and the processor PR, the memory MR, and the power module PPM may be provided in the form of other devices in the electronic device EA rather than the display device.

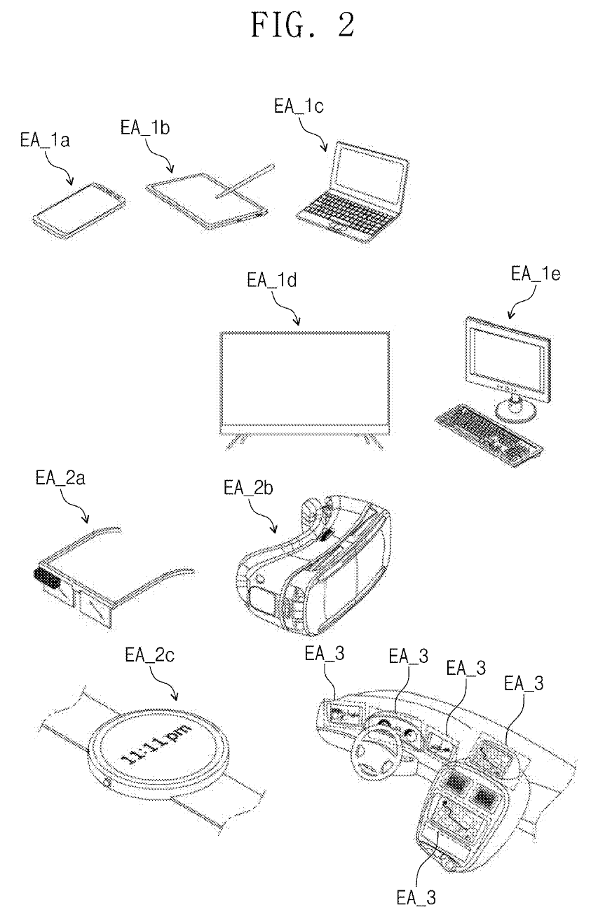

FIG. 2 is schematic views illustrating various electronic devices according to an embodiment.

Referring to FIG. 2, various electronic devices including the display module DM according to an embodiment may include an image display electronic device such as a smartphone EA_1a, a tablet personal computer (PC) EA_1b, a laptop computer EA_1c, a television (TV) EA_1d, and a desk monitor EA_1e, a wearable electronic device such as a smart glasses EA_2a, a head mounted display EA_2b, and a smart watch EA_2c, and a vehicle electronic device EA_3 such as an instrument panel, a center fascia, a center information display (CID) disposed on a dashboard, and a room mirror display of a vehicle.

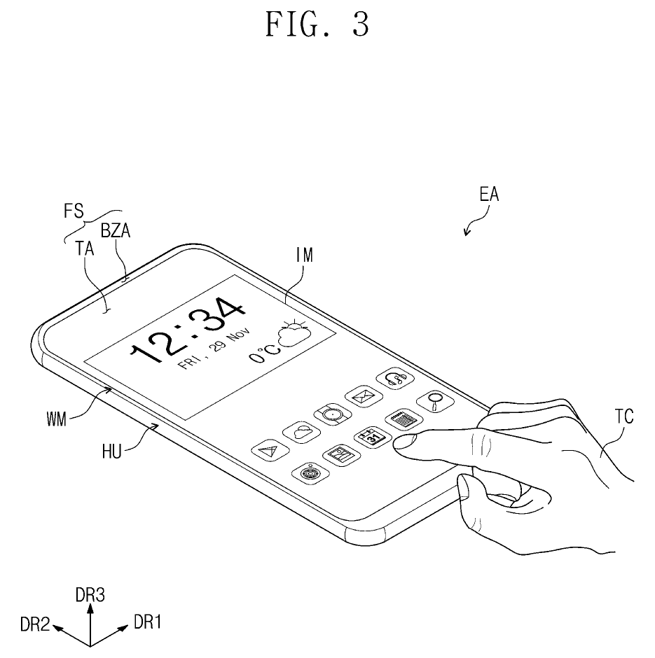

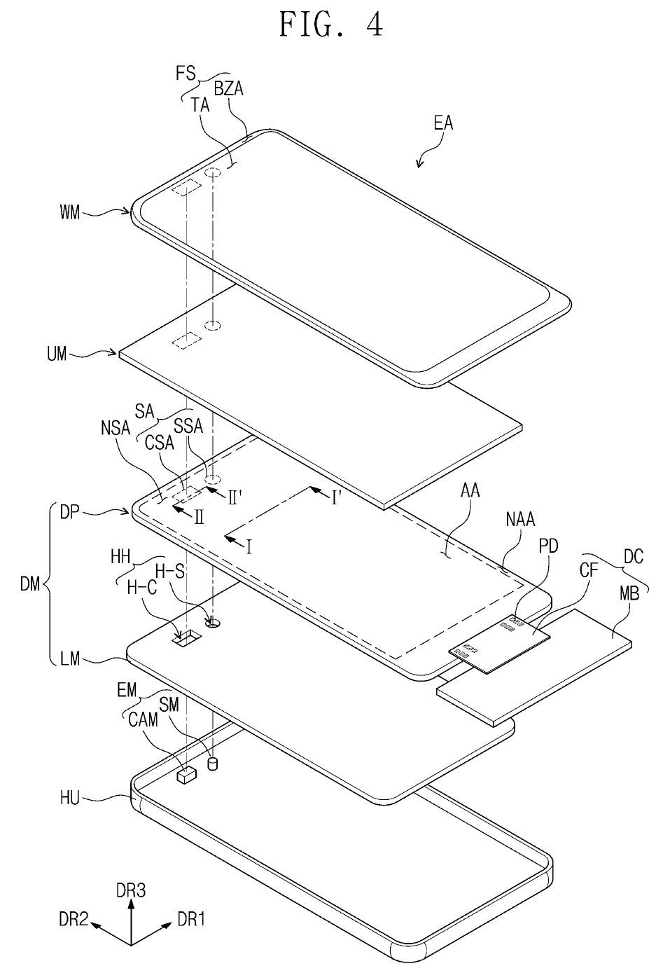

FIG. 3 is a perspective view of the electronic device EA according to an embodiment of the present disclosure. FIG. 4 is an exploded perspective view of the electronic device EA according to an embodiment of the present disclosure.

In an embodiment, by way of example, the electronic device EA is illustrated as a smart phone. However, an embodiment is not limited thereto, and the electronic device EA may be a small and medium-sized electronic device such as a mobile phone, a tablet PC, a car, a navigation device, a game console, or a smart watch as well as a large-sized electronic device such as a television or a monitor.

The electronic device EA may display an image IM in a third direction DR3, on a display surface FS parallel to a plane defined by a first direction DR1 and a second direction DR2 crossing each other. A thickness of the electronic device EA and various components or layers thereof may be defined along the third direction DR3, e.g., a thickness direction.

The display surface FS, on which the image IM is displayed, may correspond to a front surface of the electronic device EA and may correspond to a front surface FS of a window WM. Hereinafter, the same reference numeral will be used for the display surface and the front surface of the electronic device EA and the front surface of the window WM. The image IM may include a still image as well as a dynamic image. In FIG. 3, a watch and a plurality of icons are illustrated as an example of the image IM.

In an embodiment, a front surface (or a front surface) and a rear surface (or a lower surface) of each member are defined with respect to a direction in which the image IM is displayed. The front surface and the rear surface may be opposite to each other in the third direction DR3, and a normal direction of each of the front surface and the rear surface may be parallel to the third direction DR3. A separation distance between the front surface and the rear surface in the third direction DR3 may correspond to a thickness of a display panel DP in the third direction DR3 (e.g., the thickness direction). Meanwhile, directions indicated by the first direction DR1, the second direction DR2, and the third direction DR3 are relative concepts and may be changed to other directions. Hereinafter, the first direction DR1, the second direction DR2, and the third direction DR3 refer to the same reference numerals as those of the directions indicated by the first direction DR1, the second direction DR2, and the third direction DR3.

The electronic device EA according to an embodiment of the present disclosure may sense an external input TC applied from the outside. The external input TC may include various types of external inputs such a light, heat, pressure and the like, applied by an input tool such as a body part as a portion of a human body of a user. In an embodiment, the external input TC is illustrated as a hand of the user applied to the front surface. However, this is illustrated by way of example, and as described above, the external input TC may be provided in various forms, the electronic device EA may detect the external input TC applied to a side surface or a rear surface of the electronic device EA according to a structure of the electronic device EA, and the present disclosure is not limited to an embodiment.

The electronic device EA according to an embodiment may include the window WM as a window module, an upper member UM, the display module DM, a circuit board DC, and a housing unit HU.

The window WM may include an insulating panel. For example, the window WM may be made of glass, plastic, or a combination thereof.

The front surface FS of the window WM may define the display surface FS of the electronic device EA as described above. A transmissive area TA may be an optically transparent area. For example, the transmissive area TA may be an area (e.g., planar area) having a visible light transmittance of about 90% or more.

A bezel area BZA may be an area having a relatively low light transmittance as compared to the transmissive area TA. The bezel area BZA may define a planar shape of the transmissive area TA. The bezel area BZA may be adjacent to the transmissive area TA and may surround the transmissive area TA in a plan view (e.g., a view along the third direction DR3.

The bezel area BZA may have a predetermined color. The bezel area BZA may be defined by a bezel layer provided separately from a transparent substrate defining the transmissive area TA or may be defined by an ink layer formed by being inserted into or colored in the transparent substrate.

The bezel area BZA may cover a peripheral area NAA of the display module DM and prevent the peripheral area NAA from being visually recognized from the outside (e.g., outside of the electronic device EA). Meanwhile, this is illustrated by way of example, and in the window WM according to an embodiment of the present disclosure, the bezel area BZA may be omitted.

The upper member UM may include a reflection preventing layer and an input sensor layer. The reflection preventing layer may lower reflectance of external light, and the input sensor layer may sense an external input such as from the user. In this case, the upper member UM may further include an adhesive layer which couples the reflection preventing layer and the input sensor layer.

The display module DM may include the display panel DP and a lower member LM.

The display panel DP may display an image IM according to an electrical signal and transmit/receive information on an external input TC. The display panel DP may display the image IM and sense the external input TC. A front surface of the display panel DP may include an active area AA (or a display area) and the peripheral area NAA (or a non-display area).

In an embodiment, the active area AA may be an area at which the image IM is displayed, and at the same time, an area in which the external input TC is sensed. The active area AA may be an area which is activated according to an electric signal.

The peripheral area NAA may be an area covered by the bezel area BZA. The peripheral area NAA may be an area in which the image IM is not displayed. Driving circuits or driving wiring lines for driving the active area AA, and various signal lines, pads, electronic devices, or the like for providing an electrical signal to the active area AA may be arranged in the peripheral area NAA. The peripheral area NAA may be adjacent to the active area AA. The peripheral area NAA may surround the active area AA in the plan view. However, this is illustrated by way of example, the peripheral area NAA may be defined in various shapes, and the present disclosure is not limited to an embodiment. In the display panel DP according to an embodiment of the present disclosure, the peripheral area NAA may be omitted.

The active area AA may include a signal transmissive area SA and a non-transmissive area NSA. The signal transmissive area SA may be an area overlapping an electronic module EM, and the non-transmissive area NSA may be an area surrounding at least a portion of the signal transmissive area SA. The non-transmissive area NSA may be a portion of the display panel DP which corresponds to a remaining area except for the signal transmissive area SA.

The signal transmissive area SA may overlap the electronic module EM on a plane. In this case, the electronic module EM may receive an external input transmitted through the signal transmissive area SA or output a signal through the signal transmissive area SA.

The signal transmissive area SA may include a camera sensing area CSA and a sensor sensing area SSA. A camera module CAM may be disposed under the display panel DP to overlap the camera sensing area CSA, and a sensor module SM may be disposed under the display panel DP to overlap the sensor sensing area SSA. Although not illustrated, as needed, in an embodiment, a predetermined opening may be defined in layers of the display panel DP which correspond to the signal transmissive area SA of the display panel DP. Accordingly, a signal may pass through a portion of the display panel DP at such an opening.

FIG. 4 illustrates, by way of example, that the signal transmissive area SA includes the camera sensing area CSA and the sensor sensing area SSA as two signal transmissive areas SA, but the number of the signal transmissive areas SA is not limited thereto, and one or three or more signal transmissive areas SA may be defined in the display panel DP. FIG. 4 illustrates, by way of example, that the signal transmissive area SA has a circular shape or a quadrangular shape in the plan view, but the planar shape of the signal transmissive area SA is not limited thereto and may be variously defined as needed.

On a plane, a planar area of the signal transmissive area SA may be smaller than a planar area of the non-transmissive area NSA. A transmittance of the signal transmissive area SA and a transmittance of the non-transmissive area NSA may be different from each other. For example, the transmittance of the signal transmissive area SA may be greater than the transmittance of the non-transmissive area NSA.

Meanwhile, in the display panel DP according to an embodiment, a portion of a driving circuit or a driving wiring line for driving a pixel (not illustrated) disposed in the signal transmissive area SA may be disposed in the peripheral area NAA or the non-transmissive area NSA. Thus, a wiring density in the signal transmissive area SA may be lower than a wiring density in the non-transmissive area NSA. However, an embodiment is not limited thereto, and the wiring density in the signal transmissive area SA and the wiring density in the non-transmissive area NSA may be the same.

The display panel DP according to an embodiment of the present disclosure may be a light emitting display panel. For example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot or a quantum rod. Hereinafter, the organic light emitting display panel is described as the display panel DP by way of example.

The lower member LM may be disposed under the display panel DP. The lower member LM may be a member which supports the display panel DP and performs a heat dissipating function of dissipating heat generated from the display panel DP. A hole HH may be defined in the lower member LM. The hole HH may overlap the signal transmissive area SA. That is, the hole HH may overlap the electronic module EM. The hole HH may pass completely through a thickness of the lower member LM, or may extend through a partial thickness thereof.

In an embodiment, the hole HH may include a sensor hole H-S and a camera hole H-C. The sensor hole H-S may correspond to the sensor sensing area SSA, and the camera hole H-C may correspond to the camera sensing area CSA. That is, the sensor module SM may be disposed under a coating layer (not shown) to overlap the sensor hole H-S, and the camera module CAM may be disposed under the coating layer to overlap the camera hole H-C. FIG. 4 illustrates, by way of example, that the number of the holes HH defined in the lower member LM is plural, but the present disclosure is not limited thereto, and the number of holes HH may be singular. A detailed description of the lower member LM will be made below.

The electronic device EA may include the circuit board DC connected to the display panel DP. The circuit board DC may include a flexible board CF and a main board MB connected (e.g., electrically and/or physically) to each other. The flexible board CF may include an insulating film and conductive wiring lines which are mounted on the insulating film. The conductive wiring lines may be connected to the display panel DP at pads PD of the display panel DP, to electrically connect the circuit board DC to the display panel DP. Meanwhile, unlike the illustration, the flexible board CF may be omitted, and in this case, the main board MB may be directly connected to the display panel DP, such as at the pads PD.

The main board MB may include signal lines and electronic elements, which are not illustrated. The electronic elements may be connected to the signal lines and may be electrically connected to the display panel DP. In this case, the electronic elements may generate or process electrical signals. For example, the electronic elements may generate a signal for outputting the image IM and may sense and process an external input TC. Meanwhile, the main board MB may be configured in plural depending on the number of electrical signals to be generated and processed, and the present disclosure is not limited to an embodiment.

The electronic module EM may be an electronic component which outputs or receives an optical signal, such as to provide a function to the electronic device EA. For example, the electronic module EM may include the camera module CAM and the sensor module SM. The camera module CAM may receive external light through the camera sensing area CSA to capture an external image. Further, the sensor module SM may be a proximity sensor or an infrared light emitting sensor which outputs or receives external light through the sensor sensing area SSA, such as to sense an external input, etc.

The housing unit HU may be disposed under the lower member LM to accommodate the display panel DP or the like. That is, in an embodiment, the housing unit HU may be coupled to the window WM to constitute an external appearance of the electronic device EA.

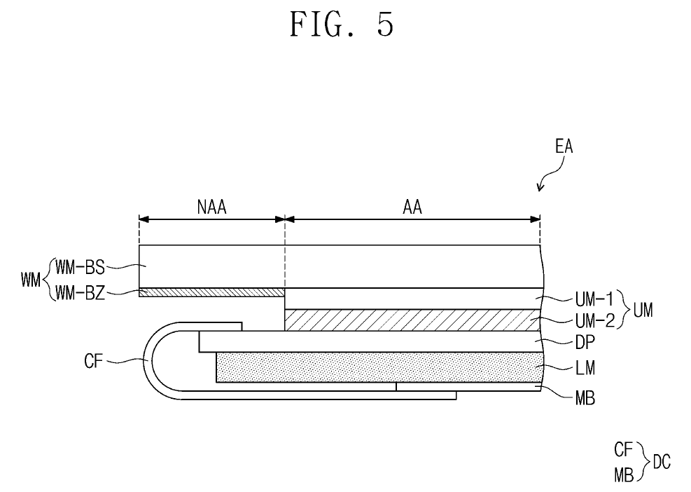

FIG. 5 is a cross-sectional view of an electronic device according to an embodiment of the present disclosure.

Referring to FIG. 5, the electronic device EA according to an embodiment of the present disclosure may include the window WM, the upper member UM, the display panel DP, the circuit board DC, and the lower member LM.

In an embodiment, the window WM may cover the front surface of the display panel DP. The window WM may include a base layer WM-BS and a bezel pattern WM-BZ.

The base layer WM-BS may include a synthetic resin film or a glass substrate. The base layer WM-BS may have a multi-layer structure. The base layer WM-BS may include a thin film glass substrate, a protective film disposed on the thin film glass substrate, and an adhesive layer which couples the thin film glass substrate and the protective film.

The bezel pattern WM-BZ may be a colored light shielding film and may be formed by, for example, a coating method. The bezel pattern WM-BZ may overlap the peripheral area NAA and the bezel area BZA illustrated in FIG. 4. The bezel pattern WM-BZ may be disposed under the base layer WM-BS. When the base layer WM-BS has a multi-layered structure, the bezel pattern WM-BZ may be disposed between interfaces defined by a plurality of layers. For example, the bezel pattern WM-BZ may be disposed between the thin film glass substrate and the protective film. FIG. 5 illustrates, by way of example, that the bezel pattern WM-BZ is disposed under the base layer WM-BS of the window WM, but the present disclosure is not limited thereto, and the bezel pattern WM-BZ may be disposed under the upper member UM.

The upper member UM may include an input sensor layer UM-2 and a reflection preventing layer UM-1.

The input sensor layer UM-2 may include a plurality of sensing electrodes (not illustrated) for sensing an external input, trace lines (not illustrated) connected to the plurality of sensing electrodes, and an inorganic layer and/or an organic layer for insulating/protecting the plurality of sensing electrodes or the trace lines. The input sensor layer UM-2 may be a capacitive sensor, but the present disclosure is not limited thereto.

The input sensor layer UM-2 may be directly disposed on the display panel DP. According to an embodiment of the present disclosure, the input sensor layer UM-2 may be formed (or provided) on the display panel DP such as through a continuous process. That is, when the input sensor layer UM-2 is directly disposed on the display panel DP, an adhesive film or other separate element for coupling the input sensor layer UM-2 and the display panel DP may be omitted. However, the present disclosure is not limited thereto, and the input sensor layer UM-2 may be manufactured as a separate panel from the display panel DP and attached to the display panel DP by a separate element such as an adhesive film.

The reflection preventing layer UM-1 may lower reflectance of external light. The reflection preventing layer UM-1 may include a phase retarder and/or a polarizer. The reflection preventing layer UM-1 may include a polarizing film or color filters. Unlike illustration in FIG. 5, an adhesive layer may be further disposed between the window WM and the reflection preventing layer UM-1. Further, FIG. 5 illustrates, by way of example, that the reflection preventing layer UM-1 is disposed on the input sensor layer UM-2, but the present disclosure is not limited thereto, and the reflection preventing layer UM-1 may be disposed between the input sensor layer UM-2 and the display panel DP.

In an embodiment, the circuit board DC may include the flexible board CF and the main board MB. The flexible board CF according to an embodiment may be assembled in a bent state extending from a front surface to a rear surface of the display panel DP. Accordingly, the main board MB may be disposed on a rear surface of the display panel DP and stably accommodated in a space provided by the housing unit HU (see FIG. 4). For example, the flexible board CF may be bent toward the rear surface of the display panel DP and disposed under the lower member LM. However, an embodiment of the present disclosure is not limited thereto, and unlike the illustration in FIG. 5, the flexible board CF may be omitted. For example, the main board MB may be directly disposed (or formed) under the lower member LM or may be mounted within the lower member LM.

In an embodiment, the lower member LM may be disposed under the display panel DP. The lower member LM may be disposed under the display panel DP and in contact with a lower surface of the display panel DP. The lower member LM may be in contact with the circuit board DC. For example, the lower member LM may be in contact with the main board MB. As being in contact, elements may form an interface (e.g., physical interface) therebetween. A detailed description of the lower member LM will be made below.

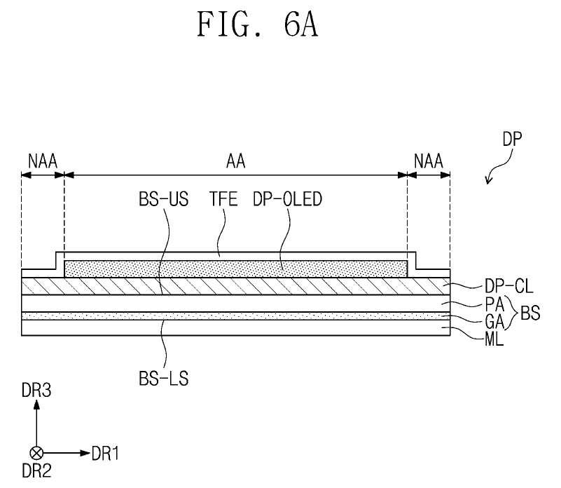

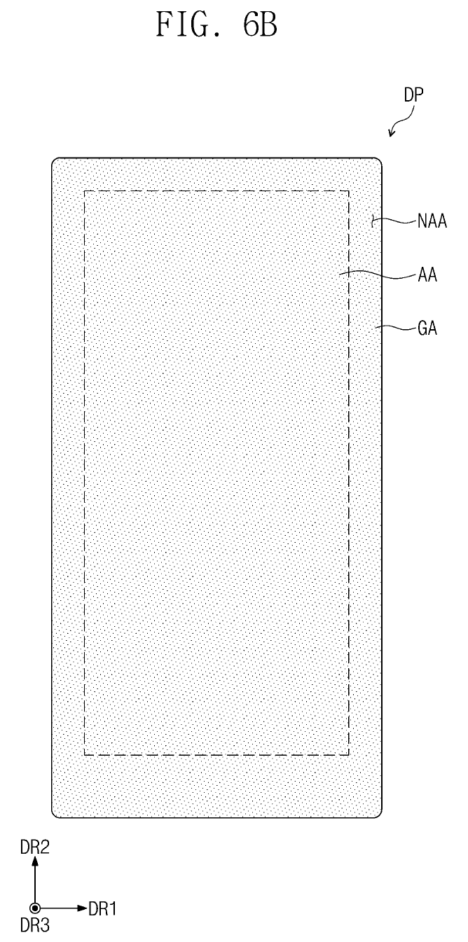

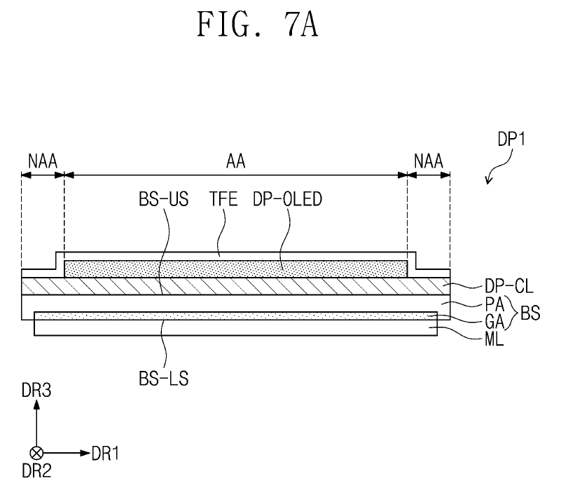

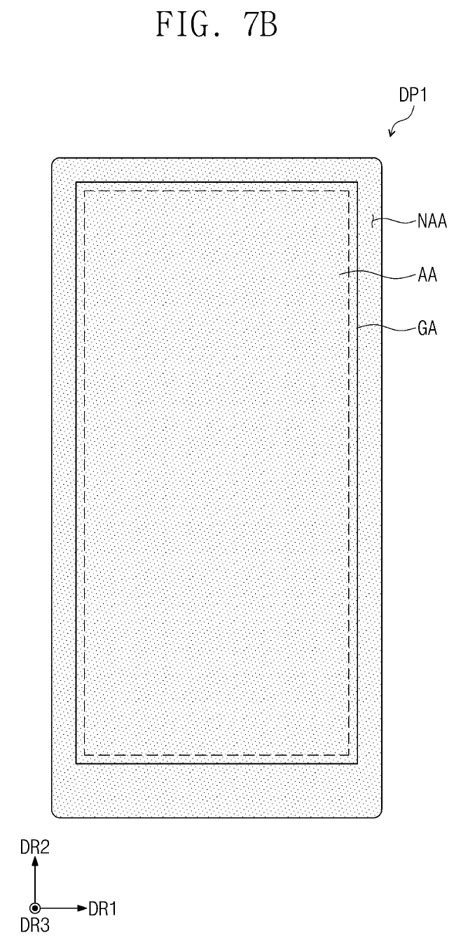

FIG. 6A is a cross-sectional view of the display panel DP according to an embodiment of the present disclosure. FIG. 6B is a rear view of the display panel DP of FIG. 6A according to an embodiment of the present disclosure. FIG. 7A is a cross-sectional view of the display panel DP1 according to an embodiment of the present disclosure. FIG. 7B is a rear view of the display panel DP1 of FIG. 7A according to an embodiment of the present disclosure.

Referring to FIG. 6A, the display panel DP may include a metal layer ML, a substrate BS, a circuit element layer DP-CL, a display element layer DP-OLED, and a thin film encapsulation layer TFE. The circuit element layer DP-CL, the display element layer DP-OLED, and the thin film encapsulation layer TFE may be sequentially arranged on the substrate BS.

The metal layer ML may be disposed on the rear surface of the substrate BS and may be in direct contact with a graphene area GA. No adhesive layer may be disposed between the metal layer ML and the graphene area GA. The metal layer ML may include any one of copper (Cu), gold (Au), silver (Ag), and platinum (Pt). A depth of the metal layer ML may be in a range of about 10 micrometers (μm) to about 50μm. The depth may indicate a total thickness or a maximum thickness, without being limited thereto. The metal layer ML may perform a heat dissipating function of dissipating heat generated by members of the electronic device EA (see FIG. 4) including the display panel DP, to the outside.

The substrate BS may be in contact with a rear surface of the circuit element layer DP-CL. The substrate BS may include the graphene area GA (or graphene layer) providing a rear surface BS-LS of the substrate BS and a polymer area PA (or a polymer layer) disposed on the graphene area GA to provide a front surface BS-US of the substrate BS. The graphene area GA may include a graphene material, and the polymer area PA may include a flexible plastic material such as polyimide (PI). For example, the polymer area PA may include at least one of polyimide, polyarylene ether, polyurethane, and polyacetylene.

A thickness of the graphene area GA may be in a range of about 1μm to about 20μm. The graphene area GA may perform a light shielding function. The graphene area GA may block light leaking toward a rear surface (or in a direction opposite to the third direction DR3) of the circuit element layer DP-CL. Further, the graphene area GA may prevent electronic components arranged under the display panel DP from being visually recognized or reflected from the outside by light emitted to the rear surface of the display panel DP.

A plurality of pixels may be arranged in the circuit element layer DP-CL and the display element layer DP-OLED. Each of the pixels may include a transistor disposed in the circuit element layer DP-CL, and a light emitting element which is disposed in the display element layer DP-OLED and connected to the transistor.

The thin film encapsulation layer TFE as an encapsulation layer may be disposed on the circuit element layer DP-CL to cover the display element layer DP-OLED. The thin film encapsulation layer TFE may protect layers or patterns forming the pixels from moisture, oxygen, and external foreign substances. Meanwhile, in an embodiment, it is illustrated that the thin film encapsulation layer TFE covers the entire area of the substrate BS, but the present disclosure is not limited thereto, and the substrate BS may include a partial area exposed outside the thin film encapsulation layer TFE. Alternatively, the area exposed from the thin film encapsulation layer TFE may be formed (or provided) along an outer edge of the substrate BS, and the present disclosure is not limited to an embodiment.

Referring to FIGS. 6A and 6B, in an embodiment of the present disclosure, the graphene area GA may be disposed on the entire rear surface of the circuit element layer DP-CL. On a plane, the graphene area GA may overlap both the active area AA and the peripheral area NAA.

Referring to FIGS. 7A and 7B, in an embodiment of the present disclosure, the graphene area GA may be disposed on a partial area of the rear surface of the circuit element layer DP-CL. On a plane, the graphene area GA may overlap the active area AA, and may not overlap at least a portion of the peripheral area NAA. An outer edge of the graphene area GA may be spaced apart from the outer edge of the circuit element layer DP-CL On a plane, an area (e.g., a total planar area) of the graphene area GA may be smaller than an area (e.g., a total planar area) of the polymer area PA. In an embodiment of the present disclosure, the graphene area GA may be disposed to overlap only the active area AA, and the peripheral area NAA which is adjacent to the active area AA on a plane, light may be selectively shielded at a portion at which a light shielding function is required, which minimizes the graphene material.

The graphene area GA may be embedded in the polymer area PA of the substrate BS. Lower surfaces of the graphene material forming the graphene area GA and the polymer material forming the polymer area PA may be coplanar with each other, without being limited thereto. Here, a layer of the polymer material may cover upper and side surface of the layer of the graphene material. That is, a thickness portion of the layer of polymer material and a thickness portion of the layer of graphene material overlaps each other in a lateral direction, e.g., along a plane (like the DR1-DR2 plane).

A planar area of the metal layer ML may be the same as the graphene area GA. The metal layer ML may protrude from the substrate BS, and have end surfaces spaced apart from end surfaces of the substrate BS.

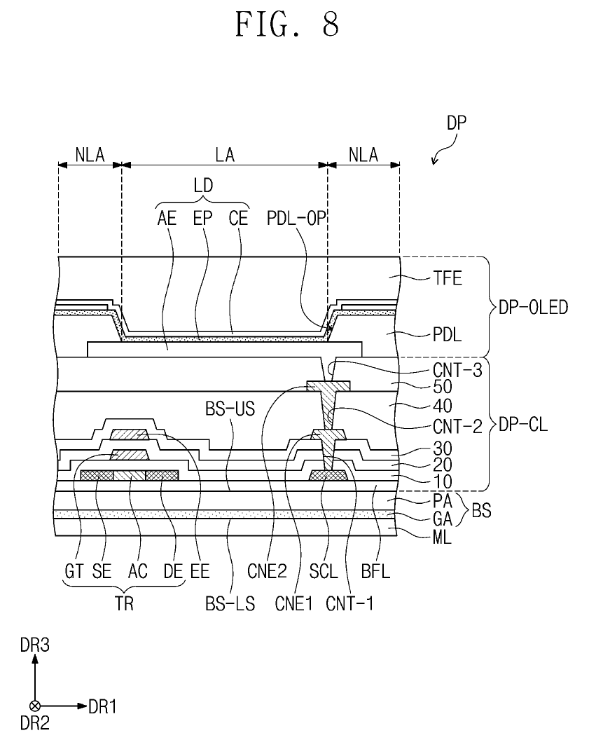

FIG. 8 is a cross-sectional view of the display panel according to an embodiment of the present disclosure. In description with reference to FIG. 8, the same/similar reference numerals are used for the same/similar components as those described in FIGS. 6A to 7B, and duplicated descriptions thereof will be omitted.

Referring to FIG. 8, the display panel DP may include the metal layer ML, the substrate BS, the circuit element layer DP-CL, the display element layer DP-OLED, and the thin film encapsulation layer TFE.

The display panel DP may include a light emitting area LA and a non-light emitting area NLA. The light emitting area LA may be an area through which light provided from a light emitting element LD is emitted. The display panel DP may include a plurality of insulating layers, a plurality of semiconductor patterns, a plurality of conductive patterns, a plurality of signal lines, and the like. The insulating layer, a semiconductor layer, and a conductive layer are formed by coating, deposition, or the like. Thereafter, the insulating layer, the semiconductor layer, and the conductive layer may be selectively patterned by photolithography and etching. In this manner, the semiconductor pattern, the conductive pattern, the signal line, and the like included in the circuit element layer DP-CL and the display element layer DP-OLED may be formed.

In an embodiment, the light emitting area LA and the non-light emitting area NLA may be disposed in a display area or an area at which an image IM is displayed. A pixel may include the light emitting area LA and the non-light emitting area NLA.

Referring to FIG. 8, the circuit element layer DP-CL may be disposed on the substrate BS. The circuit element layer DP-CL may include driving elements, a buffer layer BFL, and first to fifth insulating layers 10, 20, 30, 40, and 50. For easy description, FIG. 8 illustrates a transistor TR, a signal transmission line SCL as a signal line, and a connection electrode provided in plural including a plurality of connection electrodes CNE1 and CNE2 among the driving elements and illustrates the first to fifth insulating layers 10, 20, 30, 40, and 50 which are sequentially laminated. Meanwhile, this is illustratively illustrated, configurations or an arrangement relationship of the driving elements constituting the circuit element layer DP-CL may be variously changed, and the present disclosure is not limited to an embodiment.

The substrate BS may be disposed on the metal layer ML. As described above, the substrate BS may include the graphene area GA providing the rear surface BS-LS and the polymer area PA which is disposed on the graphene area GA to provide the front surface BS-US. The front surface BS-US of the substrate BS may be in contact with a rear surface of the buffer layer BFL, and the rear surface BS-LS of the substrate BS may be in contact with an upper surface of the metal layer ML.

The buffer layer BFL may be disposed on the substrate BS. The buffer layer BFL may improve a coupling force between the substrate BS and the semiconductor pattern. The buffer layer BFL may include a silicon oxide layer and/or a silicon nitride layer. When the buffer layer BFL includes the silicon oxide layer and the silicon nitride layer, the two layers may be alternately laminated.

The transistor TR may be disposed on the buffer layer BFL. The transistor TR may include the semiconductor pattern and a gate electrode GT.

The semiconductor pattern may be disposed on the buffer layer BFL. The semiconductor pattern may include polysilicon. However, the present disclosure is not limited thereto, and the semiconductor pattern may include an amorphous silicon or a metal oxide. FIG. 8 merely illustrates, by way of example, some semiconductor patterns, and one or more semiconductor patterns may be further arranged in a plurality of light emitting areas. The semiconductor pattern may include a plurality of areas which are distinguished according to conductivity.

The semiconductor pattern may include a source area SE, an active area AC, and a drain area DE. The active area AC may be an area having relatively lower electrical conductivity than those of the source area SE and the drain area DE. The source area SE and the drain area DE may be arranged to be spaced apart from each other with the active area AC interposed therebetween.

The gate electrode GT may be disposed between the first insulating layer 10 and the second insulating layer 20. The gate electrode GT may be disposed to overlap the active area AC of the semiconductor pattern. In an embodiment, the transistor TR is illustrated as a top-gate structure by way of example. However, this is illustrated by way of example, the gate electrode GT may be disposed under the semiconductor pattern, and the present disclosure is not limited to an embodiment.

The signal transmission line SCL may be electrically conductive. In an embodiment, the signal transmission line SCL may be disposed on (or in) the same layer as the semiconductor pattern. For example, the signal transmission line SCL may be formed (or provided) simultaneously with the semiconductor pattern. In this case, the signal transmission line SCL may be formed by forming a highly conductive area of the semiconductor pattern through a doping process or the like. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

By simultaneously forming the signal transmission line SCL and the semiconductor pattern of the transistor TR, a process may be simplified and process costs may be reduced. However, this is described by way of example, the signal transmission line SCL may be formed by patterning a conductive material such as a metal unlike the semiconductor pattern or formed on a layer different from the semiconductor pattern, and the present disclosure is not limited to an embodiment.

The source area SE, the active area AC, the drain area DE, and the signal transmission line SCL may be covered by the first insulating layer 10. The transistor TR may be covered by the second insulating layer 20.

In an embodiment, the circuit element layer DP-CL may further include an upper electrode EE. The upper electrode EE may be disposed between the second insulating layer 20 and the third insulating layer 30. The upper electrode EE may be covered by the third insulating layer 30. The upper electrode EE may at least partially overlap the gate electrode GT. The upper electrode EE may form a capacitor together with the gate electrode GT. The capacitor may be a storage capacitor constituting a pixel circuit. By further including the upper electrode EE, the capacitor and the transistor TR may be arranged to overlap each other on a plane, thereby improving a degree of integration of the pixel circuit and facilitating design of a high-resolution display panel. However, this is illustrated by way of example, the capacitor may be formed at a position which does not overlap the transistor TR, the upper electrode EE and the gate electrode GT may not form the capacitor, the upper electrode EE may be omitted, and the present disclosure is not limited to an embodiment.

The plurality of connection electrodes CNE1 and CNE2 may be arranged on the buffer layer BFL. The first connection electrode CNE1 may be disposed between the third insulating layer 30 and the fourth insulating layer 40. The first connection electrode CNE1 may be connected to the signal transmission line SCL while passing through the second insulating layer 20 and the third insulating layer 30 at a first connection contact hole CNE-1. The connection electrodes CNE1 and CNE2 may together provide a connection electrode.

The second connection electrode CNE2 may be disposed between the fourth insulation layer 40 and the fifth insulation layer 50. The second connection electrode CNE2 may be connected to the signal transmission line SCL while passing through the fourth insulating layer 40 and the fifth insulating layer 50, at a second connection contact hole CNE-1. An electrical signal flowing through the signal transmission line SCL may be transmitted to the display element layer DP-OLED through the first connection electrode CNE1 and the second connection electrode CNE2.

The display element layer DP-OLED may be disposed on the circuit element layer DP-CL. The display element layer DP-OLED may be electrically connected to the circuit element layer DP-CL The display element layer DP-OLED may include a pixel defining film PDL and the light emitting element LD.

The pixel defining film PDL may be disposed on the fifth insulating layer 50 of the circuit element layer DP-CL. A light emitting opening PDL-OP may be defined in (or provided by) the pixel defining film PDL. The light emitting opening PDL-OP may correspond to an anode AE, and the pixel defining film PDL may expose at least a portion of the anode AE to outside the pixel defining film PDL, through the light emitting opening PDL-OP. A pixel defining layer may include the pixel defining film PDL as a solid (material) portion and the light emitting opening PDL-OP may be defined by the solid portion.

The pixel defining film PDL may include an inorganic insulating material. For example, the pixel defining film PDL may include a silicon nitride (SiNₓ).

The light emitting element LD may include the anode AE (or a first electrode), a light emitting pattern EP, and a cathode CE (or a second electrode).

The anode AE may be disposed on the fifth insulating layer 50 of the circuit element layer DP-CL. The anode AE may be a transmissive electrode, a semi-transmissive electrode, or a reflective electrode. The anode AE may be connected to the second connection electrode CNE2 by a third connection contact hole CNT-3 defined through a thickness of the fifth insulating layer 50. Thus, the anode AE may be electrically connected to the signal transmission line SCL through the first connection electrode CNE1 and the second connection electrode CNE2 and thus electrically connected to the corresponding circuit element.

The anode AE may include a single-layer structure or a multi-layer structure. The anode AE may include a plurality of layers including ITO and Ag. For example, the anode AE may include a layer including the ITO (hereinafter, referred to as a lower ITO layer), a layer disposed on the lower ITO layer and including Ag (hereinafter, referred to as an Ag layer), and a layer disposed on the Ag layer and including the ITO (hereinafter, referred to as an upper ITO layer). However, the present disclosure is not limited thereto, and the anode AE may be provided as a single layer.

The light emitting pattern EP may be disposed on the anode AE. The light emitting pattern EP may include a light emitting layer including a light emitting material. The light emitting pattern EP may further include a hole injection layer (HIL) and a hole transport layer (HTL) arranged between the anode AE and the light emitting layer and may further include an electron transport layer (ETL) and an electron injection layer (EIL) arranged on the light emitting layer. The light emitting pattern EP may be referred to as an “organic layer” or an “intermediate layer.” The light emitting pattern EP may cover a portion of an upper surface of the pixel defining film PDL.

The cathode CE may be disposed on the light emitting pattern EP. The cathode CE may cover the light emitting pattern EP. The cathode CE may be commonly disposed in the pixels. That is, the cathode CE may be commonly disposed on the light emitting patterns EP of the pixels.

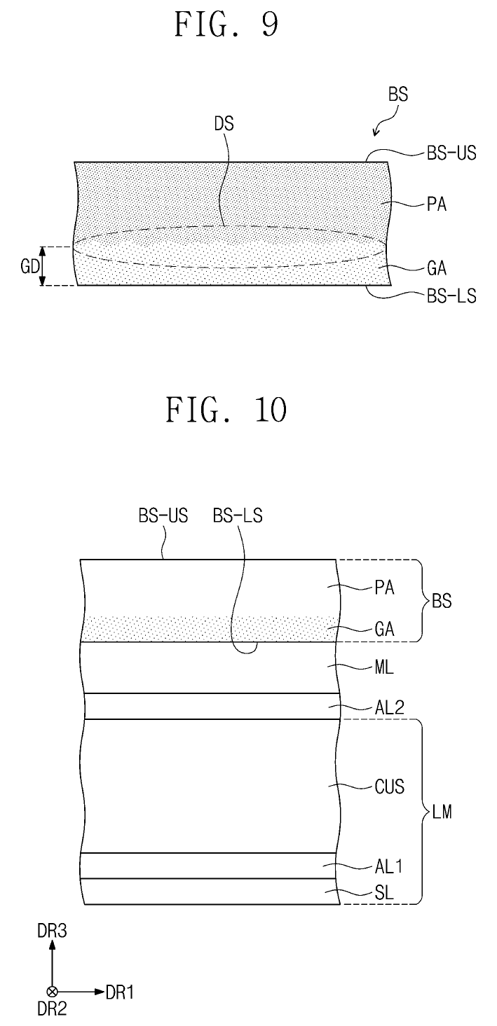

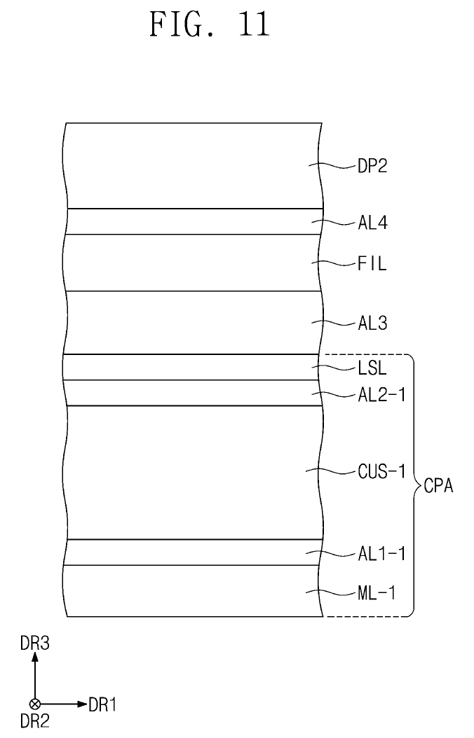

FIG. 9 is an enlarged cross-sectional view of one area of a substrate BS according to an embodiment of the present disclosure. FIG. 10 is a cross-sectional view of the electronic device EA according to an embodiment of the present disclosure. FIG. 11 is a cross-sectional view of the electronic device EA according to an embodiment of the present disclosure. In description with reference to FIGS. 9 to 11, the same/similar reference numerals are used for the same/similar components as those described in FIGS. 6 to 8, and duplicated descriptions thereof will be omitted.

Referring to FIG. 9, the substrate BS may include a graphene material layer in the graphene area GA and a polymer material layer in the polymer area PA which is disposed on the graphene area GA. A thickness GD as a thickness portion of the graphene material layer in the graphene area GA may be in a range of about 1μm to about 20μm. In this case, the substrate BS may correspond to the substrate BS illustrated in FIG. 8. In an embodiment, the range of about 1μm to about 20μm may define thicknesses of the graphene layer along the substrate BS, such as being a minimum thickness and a maximum thickness of the overall graphene layer, respectively, without being limited thereto. In an embodiment, a maximum thickness at various locations along the substrate BS may be in the range of about 1μm to about 20μm.

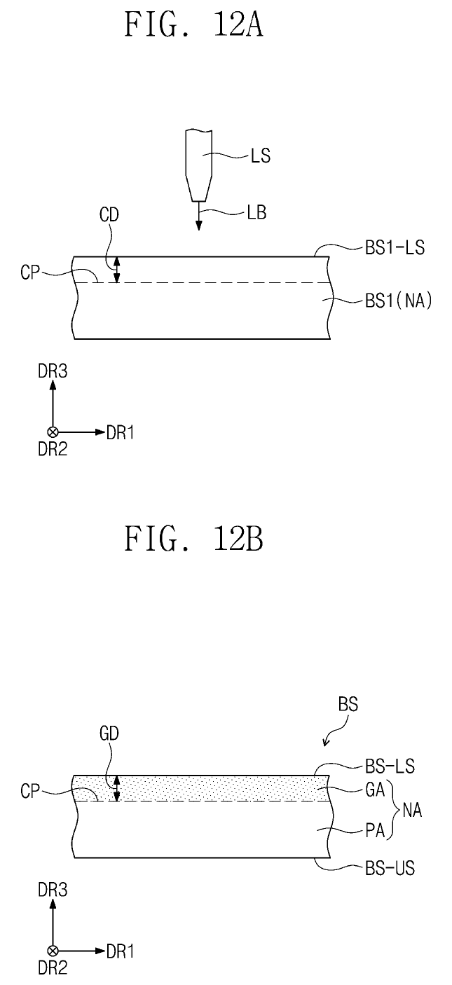

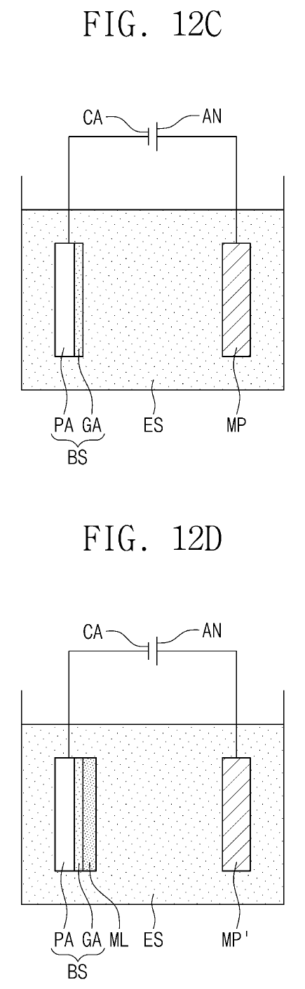

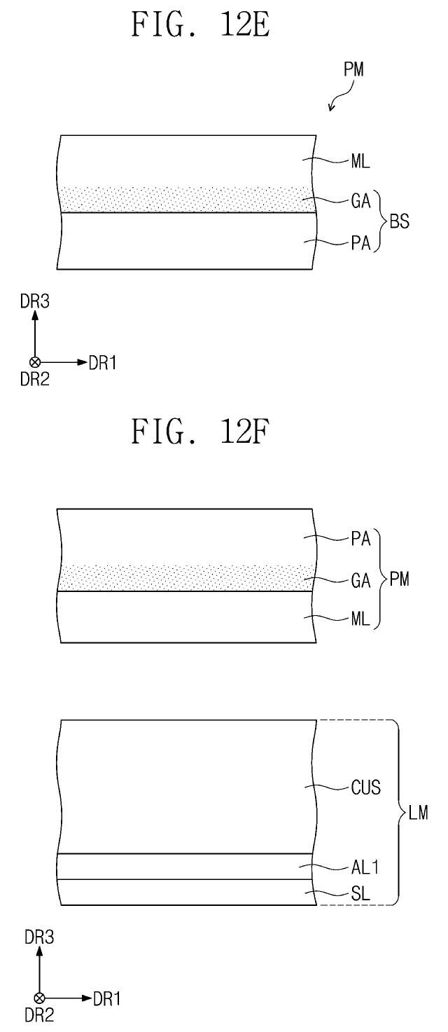

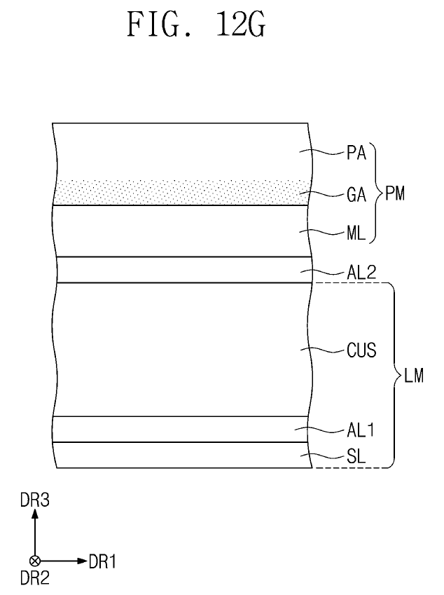

A boundary surface DS as a boundary or interface between the graphene area GA and the polymer area PA may be non-flat. In detail, the boundary surface DS between the graphene area GA and the polymer area PA may be less flat than the front surface BS-US of the substrate and may include a bent or curved portion. The graphene area GA includes graphene. The graphene area GA may be formed by carbonizing a flexible plastic material by a laser. The graphene area GA may correspond to a deformed area of the flexible plastic material which is deformed by a laser beam LB (see FIG. 12A) in a laser radiation operation, which will be described below. In the substrate BS, a cross-sectional area (or a lower thickness portion) from the rear surface BS-LS to the boundary surface DS may be an area of the laser-deformable material deformed by the laser beam LB, and a cross-sectional area (or an upper thickness portion) from the front surface BS-US to the boundary surface DS may an area of the laser-deformable material which is non-deformed area, e.g., an area or thickness portion which the laser beam LB does not reach. That is, a position of the boundary surface DS spaced apart from the rear surface BS-LS or flatness of the boundary surface DS may be controlled according to an intensity of the laser beam LB and from which surface the laser beam LB is applied to the laser-deformable material. A detailed description therefor will be described below.

Referring to FIG. 10, an electronic device EA according to an embodiment of the present disclosure may include the lower member LM disposed under the metal layer ML. The lower member LM may include a cushion layer CUS, a support layer SL, and an adhesive layer AL1.

The cushion layer CUS may be disposed below the metal layer ML, such as to be closest to the metal layer ML among layers of the lower member LM, without being limited thereto. The cushion layer CUS may include a material having impact resistance. For example, the cushion layer CUS may include an acryl-based polymer resin or a urethane-based polymer resin. A depth (or thickness) of the cushion layer CUS may be in a range of about 100μm to about 300μm. As the cushion layer CUS has impact resistance, the display panel DP may be protected from external impact or interference transmitted toward the rear surface of the display panel DP.

The support layer SL may be disposed below the cushion layer CUS, such as to be furthest from the metal layer ML among layers of the lower member LM, without being limited thereto. The support layer SL may be disposed at a lowermost portion of the components of the lower member LM. In this case, the support layer SL may be in contact with the circuit board DC (see FIG. 5). A depth of the support layer SL may be in a range of about 20μm to about 150μm. The support layer SL may include a transparent material.

The first adhesive layer AL1 may be disposed between the support layer SL and the cushion layer CUS to couple the support layer SL and the cushion layer CUS to each other.

The lower member LM may be attached to the metal layer ML through a second adhesive layer AL2. In this case, the metal layer ML may be in contact with the rear surface BS-LS of the substrate BS and the second adhesive layer AL2.

Referring to FIG. 11, an electronic device EA according to an embodiment may include a display panel DP2, a cover panel CPA disposed below the display panel DP2, and a film layer FIL disposed between the display panel DP2 and the cover panel CPA. The cover panel CPA may be disposed below the display panel DP2 to perform heat dissipating, light shielding, and/or protecting functions.

The cover panel CPA may include a light shielding layer LSL, a cushion layer CUS-1, a metal layer ML-1, and a plurality of adhesive layers AL1-1 and AL2-1.

The light shielding layer LSL may include a light shielding material. For example, the light shielding layer LSL may include a black pigment or a black dye, and may have a light shielding function.

The adhesive layers AL1-1 and AL2-1 may be disposed between the metal layer ML-1 and the cushion layer CUS-1 and between the cushion layer CUS-1 and the light shielding layer LSL, to attach the cushion layer CUS-1 to the metal layer ML-1 and the light shielding layer LSL, respectively.

The cover panel CPA may be attached to the film layer FIL through a third adhesive layer AL3. In this case, the third adhesive layer AL3 may be formed by deforming a preliminary adhesive layer (not illustrated) having an embossed pattern (e.g., non-flat surface) formed on an upper surface thereof. Before the light shielding layer LSL and a film layer FIL are coupled to each other, the preliminary adhesive layer including the embossed pattern may be deformed (e.g., compressed) during a process of coupling the two components, and as a result, the third adhesive layer AL3 having a flat upper surface may be formed from the compressed embossed pattern.

When the cover panel CPA and the display panel DP2 are coupled to each other, the film layer FIL may serve to reinforce the coupling therebetween and provide structural stability. The film layer FIL may be attached to the display panel DP2 through a fourth adhesive layer AL4.

According to the present disclosure, the metal layer ML may be disposed under the graphene area GA and in contact with the graphene area GA. That is, unlike an embodiment described with reference to FIG. 11, according to the present disclosure, an additional adhesive layer for coupling the metal layer ML to other components, e.g., the first adhesive layer AL1-1 according to an embodiment, may be omitted. Here, the substrate BS according to one or mor embodiment may serve to couple the metal layer ML to other components.

Further, according to the present disclosure, the graphene area GA may serve to shield light, and thus the light shielding layer LSL for serving to shield light and the separate adhesive layer for coupling the light shielding layer LSL to other components among the components of the existing cover panel may be omitted. That is, the base substrate BS may provide a light shielding function together with an adhesive function for shielding light and for coupling the cover panel CPA to other components, such as in place of the light shielding layer LSL and the separate adhesive layer.

In addition, the metal layer ML having high thermal stability may be disposed under the graphene area GA, and thus the display panel DP may be directly coupled to the lower member LM without a separate interposed layer (refer to FIG. 5, for example). Accordingly, the plurality of layers may be omitted, thereby simplifying a process and reducing costs.

In an embodiment, for example, an electronic device EA includes a window module (like the window WM), a display panel DP facing the window module, and a lower member LM facing the window module with the display panel DP therebetween. The display panel DP includes a substrate BS including a polymer area PA as a polymer layer providing a front surface facing the window module, and a graphene area as a graphene layer which is on the polymer area and provides a rear surface opposite to the front surface, a pixel on the substrate BS, and a metal layer ML on the rear surface of the substrate BS.

The lower member LM may include a cushion layer CUS and a support layer SL facing the cushion layer CUS. An adhesive layer (like AL2) may be between the lower member LM and the substrate BS. The metal layer ML may be in contact with the graphene area GA of the substrate BS and the adhesive layer.

Within the substrate BS, a boundary (like DS)_may be between the graphene area GA and the polymer area PA and may be less flat than the front surface of the substrate BS.

The pixel may include a circuit element layer DP-CL and a display element layer DP-OLED in order from the substrate BS. The front surface of the substrate BS may be in contact with the circuit element layer DP-CL.

FIGS. 12A to 12G are cross-sectional views illustrating some of operations of a method for manufacturing (or providing) an electronic device EA according to an embodiment of the present disclosure. In description with reference to FIGS. 12A to 12G, the same/similar reference numerals are used for the same/similar components as those described in FIGS. 6 to 11, and duplicated descriptions thereof will be omitted.

FIG. 12A illustrates an operation of radiating the laser beam LB to one surface BS1-LS of an initial substrate (BS1). In this case, the initial substrate BS1 may include a flexible plastic material such as polyimide (PI), which is laser deformable. For example, the initial substrate BS1 may include at least one of polyimide, polyarylene ether, polyurethane, and polyacetylene. The material of the initial substrate BS1 is not limited thereto and may be variously modified as long as the material may be carbonized to form a graphene material.

Referring to FIGS. 12A and 12B, the laser beam LB may be radiated from a laser radiation unit LS, toward the initial substrate BS1 through the initial substrate BS1. The initial substrate BS1 before radiation and the substrate BS provided after radiation, may include a total thickness otherwise defined as a normal area NA. For example, FIGS. 12A and 12B may include the normal area NA both above and below a virtual boundary (e.g., a central point CP), to define a total thickness. The normal area NA may also define a total thickness portion which includes both the graphene layer and the polymer layer along a thickness direction.

A radiation depth CD of the laser beam LB may be in a range of about 1μm to about 20μm from the surface BS1-LS. When the laser beam LB is radiated into the initial substrate BS1 from the surface BS1-LS, a partial cross-sectional area of the initial substrate BS1, in which the laser beam LB is absorbed, may be deformed. In detail, at least a portion of a normal area NA of the initial substrate BS1 including a laser-deformable polymer may absorb the laser beam LB and thus may be deformed into the graphene area GA. An area (e.g., cross-sectional area or thickness portion) of the normal area NA deformed by application of the laser beam LB may correspond to the graphene area GA of FIG. 9, and an area of the normal area NA which is outside of the radiation depth CD and not deformed by non-arrival of the laser beam LB may correspond to the polymer area PA of FIG. 9.

A partial area of the initial substrate BS1 may be carbonized by absorbing thermal energy of the laser beam LB, and accordingly, a molecular structure of the corresponding area may be deformed to form the graphene area GA.

The graphene area GA may be formed to a central point CP as a virtual boundary or virtual line spaced apart from the one surface BS1-LS of the initial substrate BS1 by a certain depth GD on a cross section. The certain depth GD may correspond to the radiation depth CD at which the laser beam LB is radiated.

The laser beam LB may be any one of an ultraviolet laser (UV laser), a green laser, an infrared laser (IR laser), and a carbon dioxide laser (CO₂ laser).

Referring to FIGS. 12C to 12E, after an operation of radiating the laser beam LB, an operation of forming the metal layer ML on the graphene area GA may be performed. For easy description, FIGS. 12C and 12D illustrate the substrate BS having a relatively reduced size for convenience of explanation. The substrate BS illustrated in FIGS. 12C and 12D may correspond to the substrate BS illustrated in FIG. 12E, and the metal layer ML illustrated in FIGS. 12C and 12D may correspond to the metal layer ML illustrated in FIG. 12E.

The metal layer ML may be formed by an electroplating method. For example, in an embodiment, the operation of forming the metal layer ML may include an operation of providing the substrate BS including the graphene area GA and the polymer area PA (together as the normal area NA) to an electrolytic solution ES, an operation of providing a metal plate MP to the electrolytic solution ES such that the metal plate MP is spaced apart from the substrate BS, and an operation of applying a voltage to the substrate BS at the graphene area GA and to the metal plate MP.

After the substrate BS is set to a negative electrode CA and the metal plate MP is set to a positive electrode AN, when a uniform electric field is formed in the electrolytic solution ES, metal ions may be deposited on the graphene area GA. The metal plate MP and the electrolytic solution ES may include the same metal. In this case, metal ions included in the electrolytic solution ES may be precipitated on a surface of the substrate BS, at the graphene area GA. The metal layer ML may be formed by coating the graphene area GA with the metal.

In an embodiment of the present disclosure, the metal may be copper (Cu), and the electrolytic solution ES may be a CuSO₄ solution. However, the metal is not limited thereto, and the electrolytic solution ES may include ions of at least one of copper (Cu), gold (Au), silver (Ag) and platinum (Pt).

Referring to FIG. 12E, a panel member PM may include thickness portions of the polymer area PA, the graphene area GA and the metal layer ML, in order along the thickness direction. While a solid line is shown between the polymer layer and the graphene layer in FIG. 12E, it will be understood that the boundary between the polymer material and the graphene material may be a transition from one material to another along the thickness direction such as that shown in FIG. 12F. While no boundary is explicitly shown between the graphene layer and the metal layer ML in FIG. 12E, it will be understood that the boundary between the graphene material and the metal material may be a defined interface between the two materials, like the solid line in FIG. 12F.

Referring to FIGS. 12F and 12G, a method of manufacturing an electronic device EA according to an embodiment of the present disclosure may further include an operation of providing the lower member LM, and an operation of attaching the lower member LM to a panel member PM manufactured by the manufacturing method described with reference to FIGS. 12A to 12E. In this case, the lower member LM may correspond to the lower member LM described above with reference to FIG. 10. The lower member LM may include the support layer SL, the cushion layer CUS disposed on the support layer SL, and the first adhesive layer AL1 disposed between the support layer SL and the cushion layer CUS. The lower member LM may be attached to the panel member PM by the second adhesive layer AL2. In this case, an upper surface of the second adhesive layer AL2 may be flat. That is, as described above, the upper surface of the second adhesive layer AL2 may not include an embossed pattern.

Although not illustrated, the method of manufacturing an electronic device EA according to an embodiment of the present disclosure may further include an operation of forming the pixel on the substrate BS, at the normal area NA (see FIG. 12A). In this case, the operation of forming the pixel may be performed after the operation of forming the metal layer ML or before the operation of forming the metal layer ML, and the present disclosure is not limited to an embodiment.

In the operation of attaching the lower member LM to the panel member PM, bubbles may be generated, and the generated bubbles may be visually recognized from the front surface of the display panel DP. In order to prevent the generation of the bubbles, a an adhesive layer in which an embossed pattern is defined on an upper surface thereof may be generally used when the lower member LM and the display panel DP are coupled to each other. According to the present disclosure, as the graphene area GA serving as a light shielding layer is formed overlapping an planar area of the display panel DP, even when the bubbles are generated when the lower member LM is attached to the panel member PM, the bubbles may be prevented from being visually recognized on a front surface of the display panel DP, and a bubble recognition problem may be solved without using an adhesive layer having an embossed pattern on an upper surface thereof.

Further, as described above, as the metal layer ML may be directly formed on the substrate BS at the graphene area GA in an electroplating method, a separate adhesive layer for coupling the metal layer ML may be omitted, and a separate interposed layer may be omitted as described above.

In this way, since some of the components of the existing cover panel CPA of a conventional electronic device (see FIG. 11) may be omitted, an overall thickness of the electronic device EA may be relatively reduced, and manufacturing costs of the electronic device EA may be relatively reduced.

In an embodiment, for example, a method of providing an electronic device EA includes providing an initial substrate BS1 having a total thickness of a polymer material, radiating a laser beam to one surface of the initial substrate S1 to change a thickness portion of the polymer material to a graphene area GA, where a substrate BS of the electronic device EA includes the graphene area GA and a polymer area PA as a remainder of the total thickness of the polymer material which faces the graphene area GA, providing a pixel overlapping the graphene area GA of the substrate BS, providing a metal layer ML of the electronic device EA on the graphene area GA to provide a panel member PM including the substrate BS and the metal layer ML, and attaching a lower member LM of the electronic device EA to the panel member PM at the metal layer ML.

A thickness of the thickness portion of the polymer material which is changed to the graphene area GA may correspond to the radiation depth of the laser beam LB from the one surface of the initial substrate BS1.

The providing of the metal layer ML may include providing the substrate BS of the electronic device EA in an electrolytic solution ES, providing a metal plate MP in the electrolytic solution ES and spaced apart from the substrate BS, the metal plate MP and the electrolytic solution ES including a same metal, and applying a voltage to the substrate BS at the graphene area GA and to the metal plate MP. The metal layer ML may be defined by coating the same metal on the graphene area GA of the substrate BS.

According to the present disclosure, an electronic device EA may be provided in which, as a graphene area GA and a metal layer ML are formed under a same side of a polyimide substrate disposed at a lowermost portion of a display panel DP, some of components included in the existing cover panel may be omitted. Thus, costs for manufacturing the cover panel are reduced, and a thickness of the electronic device is reduced.

Although the description has been made above with reference to an embodiment of the present disclosure, it may be understood that those skilled in the art or those having ordinary knowledge in the art may variously modify and change the present disclosure without departing from the spirit and technical scope of the present disclosure described in the appended claims. Thus, the technical scope of the present disclosure is not limited to the detailed description of the specification but should be defined by the appended claims.

What is claimed is:

1. An electronic device comprising:
a window module;
a display panel facing the window module, the display panel including:
a substrate including:
a polymer area providing a front surface facing the window module, and
a graphene area on the polymer area and providing a rear surface opposite to the front surface,
a pixel on the substrate, and
a metal layer on the rear surface of the substrate; and
a lower member facing the window module with the display panel therebetween.

2. The electronic device of claim 1, wherein the polymer area includes at least one of polyimide, polyarylene ether, polyurethane and polyacetylene.

3. The electronic device of claim 1, wherein the lower member includes:
a cushion layer;
a support layer disposed below the cushion layer; and
an adhesive layer disposed between the cushion layer and the support layer.

4. The electronic device of claim 3, further comprising:
a circuit board which is connected to the display panel and in contact with the lower member at the support layer.

5. The electronic device of claim 3, wherein the metal layer is in contact with the graphene area of the substrate and the adhesive layer.

6. The electronic device of claim 1, wherein a boundary between the graphene area and the polymer area is less flat than the front surface of the substrate.

7. The electronic device of claim 1, wherein the metal layer is in contact with the graphene area.

8. The electronic device of claim 1, wherein the metal layer includes any one of copper, gold, silver and platinum.

9. The electronic device of claim 1, wherein
the pixel includes a circuit element layer and a display element layer in order from the substrate, and
the front surface of the substrate is in contact with the circuit element layer.

10. The electronic device of claim 1, wherein a thickness of the graphene area is in a range of about 1 micrometer to about 20 micrometers.

11. The electronic device of claim 1, wherein a planar area of the graphene area is smaller than a planar area of the polymer area.

12. A method of providing an electronic device, the method comprising:
providing an initial substrate including a normal area;
radiating a laser beam to one surface of the initial substrate so that a portion of the normal area is formed as a graphene area;
providing a pixel on the normal area;
providing a metal layer on the graphene area; and
attaching a lower member to the metal layer.

13. The method of claim 12, wherein, in the radiating of the laser beam, the laser beam is any one of an ultraviolet laser, a green laser, an infrared laser and a carbon dioxide laser.

14. The method of claim 12, wherein, in the radiating of the laser beam, a radiation depth of the laser beam is in a range of about 1 micrometer to about 20 micrometers.

15. The method of claim 14, wherein the graphene area is formed to a central point spaced apart from the one surface of the initial substrate by a certain depth on a cross section, and
wherein the certain depth corresponds to the radiation depth of the laser beam from the one surface.

16. The method of claim 12, wherein the providing of the metal layer includes:
providing the substrate including the graphene area and the normal area to an electrolytic solution;
providing a metal plate in the electrolytic solution and spaced apart from the substrate, the metal plate and the electrolytic solution including a same metal; and
applying a voltage to the substrate at the graphene area and to the metal plate.

17. The method of claim 16, wherein the electrolytic solution includes an ion of any one of copper, gold, silver and platinum.

18. The method of claim 16, wherein the metal layer is defined by coating the same metal on the graphene area of the substrate.

19. The method of claim 12, wherein the providing of the pixel is performed after the providing of the metal layer on the graphene area.

20. The method of claim 12, wherein the providing of the pixel is performed before the providing of the metal layer on the graphene area.
